(19) United States
(12) Patent Application Publication
(10) Pub. No.: US 2015/0282367 A1
(43) Pub. Date: Oct. 1, 2015

(54) ELECTRONIC ASSEMBLY THAT INCLUDES STACKED ELECTRONIC COMPONENTS

(71) Applicants: Hans-Joachim Barth, Munich (DE); Reinhard Mahnkopf, Oberhaching (DE); Sven Albers, Regensburg (DE); Thorsten Meyer, Regensburg (DE)

(72) Inventors: Hans-Joachim Barth, Munich (DE); Reinhard Mahnkopf, Oberhaching (DE); Sven Albers, Regensburg (DE); Thorsten Meyer, Regensburg (DE)

(21) Appl. No.: 14/227,977

(22) Filed: Mar. 27, 2014

(51) Int. Cl. H05K 7/02; H05K 13/00; H05K 3/36

(52) U.S. Cl. CPC H05K 7/02; H05K 7/023; H05K 3/36; H05K 13/0023; H05K 2203/06

(57) ABSTRACT

An electronic assembly that includes a first electronic component that includes a first substrate having a front side and a back side and at least one electronic assembly mounted on the front side of the first substrate, a second electronic component that includes a second substrate having a front side and a back side and at least one electronic assembly mounted on the front side of the second substrate, and wherein the back side of the first substrate is directly attached to the back side of the second substrate.

### TECHNICAL FIELD

Embodiments described herein generally relate to electronic assemblies, and more particularly to electronic assemblies that include stacked electronic components.

### BACKGROUND

Mobile products (e.g., mobile phones, smart phones, tablet computers, etc.) are very restricted in available space because there are typically severe limitations for chip and package area and height (among other physical and electrical parameters). Therefore, it is extremely important to reduce the size of electronic components (e.g., packaged chips or discrete devices, integrated passive devices (IPDs), surface mount devices (SMDs), etc.) on a system board (e.g., printed circuit board PCB).

Typically electronic chips, integrated circuits (ICs) or integrated passive devices (IPDs) have their functional elements or functional devices only on one side (e.g., the front side) of their respective substrates. One exception is where the backside of the substrate is used as a common ground (i.e., electrical management). Another exception is where the backside of the substrate is used as a heat sink (i.e., thermal management).

FIG. 1 illustrates an example prior art electronic component 1. As used herein, electronic component includes (among other devices) integrated circuits (IC) or integrated passive devices (IPD). FIG. 2 illustrates another example prior art electronic component 2 that includes through silicon or through substrate vias (TSVs) 3. In the example prior art electronic component 2 illustrated in FIG. 2, the back side of the chip or silicon interposer may be used to connect the TSVs 3 to a redistribution layer (RDL) 4 and designated I/O pads. As an example, the I/O pads may be formed by various known manufacturing techniques (e.g., flip-chip (FC), micro flip-chip (μ-FC) pads or Cu pillars, etc.).

The one-sided utilization of the respective substrates in conventional electronic components causes a significant amount of space to be consumed on system boards (e.g., PCBs). In addition, conventional electronic components typically require a significant amount of height making them more difficult to fit inside a housing of mobile products, especially when several chips, IPDs or SMDs need to be assembled and/or stacked one on top of another.

### BRIEF DESCRIPTION OF THE DRAWINGS

FIG. 1 illustrates an example prior art electronic component.

FIG. 2 illustrates another example prior art electronic component that includes through silicon or through substrate vias (TSVs).

FIG. 3 illustrates an example electronic assembly.

FIG. 4 illustrates another example electronic assembly.

FIGS. 5A-B illustrate example electronic packages that include the electronic assembly shown in FIG. 3.

FIGS. 6A-D illustrate other example electronic packages and process flows for making the electronic packages that include the electronic assembly shown in FIG. 3.

FIG. 7 illustrates an example electronic system that includes the electronic assembly shown in FIG. 3.

FIG. 8 is a flow diagram illustrating a method of stacking electronic components to form an electronic assembly.

FIG. 9 is block diagram of an electronic apparatus that includes the electronic assemblies and/or the electronic packages described herein.

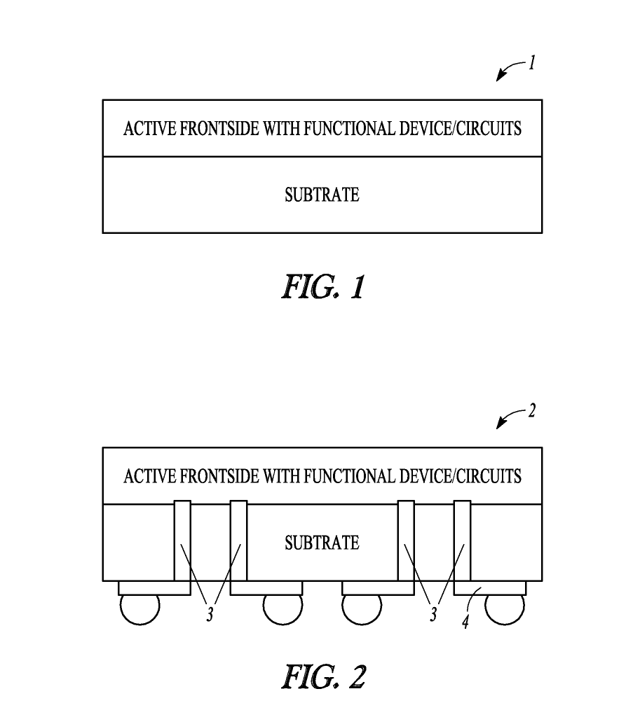

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Orientation terminology, such as “horizontal,” as used in this application is defined with respect to a plane parallel to the conventional plane or surface of a wafer or substrate, regardless of the orientation of the wafer or substrate. The term “vertical” refers to a direction perpendicular to the horizontal as defined above. Prepositions, such as “on,” “side” (as in “sidewall”), “higher,” “lower,” “over,” and “under” are defined with respect to the conventional plane or surface being on the top surface of the wafer or substrate, regardless of the orientation of the wafer or substrate.

The electronic assemblies described herein include back-to-back attachment of two or more electronic components (e.g., dies) prior to the embedding the dies into a laminate (or some other type of packaging layer). This back-to-back attachment of two or more electronic components may serve to optimize packaging options for electronic assemblies that include the electronic components.

In addition, back-to-back attachment of two or more electronic components utilizes previously “wasted area” on the back side of each respective electronic component. Therefore, the amount of functional devices or circuits per electronic assembly area may be doubled compared to the conventional electronic assemblies that use just one side of a substrate.

In addition, valuable area on the system board may be saved, and/or the height of the electronic packages that include the electronic assemblies described herein may be reduced compared to traditional stacking techniques, (e.g., package-on-package (PoP)). The electronic assemblies described herein may also permit different functional dies to be brought closer together thereby reducing parasitics between the electronic components that form the electronic assemblies (and the electronic packages that include the electronic assemblies).

The electronic assemblies described herein may include functional devices on the front side of each of the back-to-back mounted electronic components. Therefore, the functional devices are in effect mounted on the front and backside of the electronic assembly.

Examples of functional devices include, but are not limited to, transistors, diodes, electronic circuit elements according to CMOS, Bipolar, BiCMOS, Analog/Mixed Signal, RF, Power-Semiconductor DRAM, SRAM or NVM memory technologies. In addition, optional passive devices may be mounted on the front and back side of each of the electronic assemblies described herein. Example optional passive devices include, but are not limited to, resistors, capacitors (MOS caps, MIM caps, intermetal caps) and inductors (coils) during FEOL or BEOL processing.

As discussed above, one potential benefit of mounting functional devices on the front and backside of the electronic assembly is that a relatively higher number of functional devices may be included in a given area and/or volume within an electronic package. Another potential benefit of mounting functional devices on the front and back side of an electronic assembly is that such electronic assemblies may more easily permit a mix of different technology generations (e.g., 20 nm, 40 nm, 65 nm, etc. CMOS) to be included in an electronic package. In addition, mounting functional devices on the front and back side of an electronic assembly may more easily permit a mix of different manufacturing technologies (e.g., CMOS logic, DRAM, NVM memory, Bipolar, Analog/Mixed signal, RF, Power-semiconductor technologies etc. and various passive devices) to be included in an electronic package that includes the electronic assembly.

Mounting functional devices on the front and back side of the electronic assembly may also improve the manufacturability of the various electronic components that form the electronic assembly. One possible reason for the improved manufacturability of the various electronic components is that designated optimal manufacturing conditions may be used to fabricate the individual electronic components (e.g., dies) that form the electronic assembly.

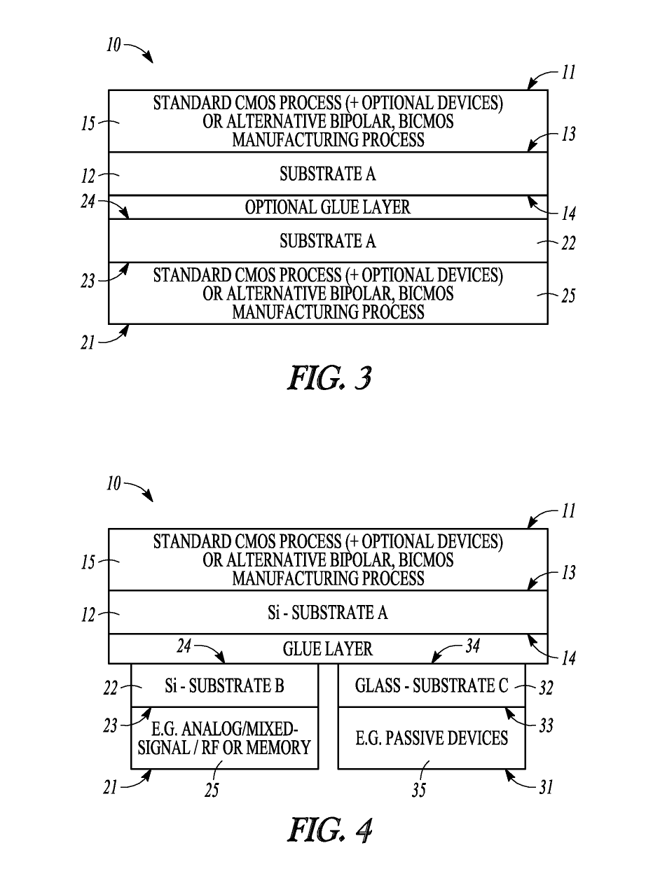

FIG. 3 illustrates an example electronic assembly 10. The electronic assembly 10 includes a first electronic component 11 that includes a first substrate 12 having a front side 13 and back side 14, and at least one electronic device 15 mounted on the front side 13 of the first substrate 12.

The electronic assembly 10 further includes a second electronic component 21 that includes a second substrate 22 having a front side 23 and a back side 24, and at least one electronic device 25 mounted on the front side 23 of the second substrate 22.

The back side 14 of the first substrate 12 is directly attached to the back side 24 of the second substrate 22. In some forms, the back side 14 of the first substrate 12 is directly adhered (e.g., by gluing, direct silicon-to-silicon bonding, anionic bonding, etc.) to the back side 24 of the second substrate 22.

It should be noted that the back side 14 of the first substrate 12 may be directly attached to the back side 24 of the second substrate 22 in any manner that is known now or discovered in the future. The manner in which the back side 14 first substrate 12 is directly attached to the back side 24 of the second substrate 22 will depend in part on the type of electronic components 11, 21 that are used in the electronic assembly (among other factors).

In some example forms of the electronic assembly 10, at least one of the first substrate 12 and the second substrate 22 is a silicon substrate. In still other example forms of the electronic assembly 10, at least one of the first substrate 12 and the second substrate 22 is a glass substrate. Other example materials for the first substrate 12 and the second substrate 22 include, but are not limited to, silicon, glass, silicon on isolator, silicon carbide (SiC), gallium arsenide, organic substrates and laminates, etc. It should be noted that the first substrate 12 and the second substrate 22 may be the same material or different materials.

As discussed in part above, attaching the back side 14 of the first substrate 12 directly to the back side 24 of the second substrate 22 may allow the electronic assembly 10 to inherently to have double the density of electronic components for a given area occupied by the electronic assembly 10. Potentially doubling the density of electronic components for a given area may permit the electronic assembly 10 to create smaller, faster and more powerful electronic packages that include the electronic assembly 10.

In addition, the individual electronic components (e.g., logic dies, memories, RF, analog-mixed signal dies, passive devices, integrated passive devices (IPDs), sensors, components of optical data transmission, etc.) that may be utilized in the electronic assembly 10 may be manufactured with optimized processing technologies (e.g., advanced CMOS, BICMOS, Bipolar, RF, analog/mixed signal, DRAM-, SRAM- or Non-volatile- (NVM) memory technologies, sensor technologies, etc.). The individual electronic components may also make use of optimized substrates (e.g., standard or high ohmic Si substrates, GaAs, III/V substrates, II/VI substrates, dielectric substrates, etc.) for each electronic component that is part of the electronic assembly 10.

FIG. 4 illustrates another example form for the electronic assembly 10. As shown in FIG. 4, the electronic assembly 10 may further include a third electronic component 31 that includes a third substrate 32 having a front side 33 and a back side 34, and at least one electronic device 35 mounted on the front side 33 of the third substrate 32. In the example form of the electronic assembly 10 shown in FIG. 4, the back side 34 of the third substrate 32 may be directly attached to the back side 14 of the first substrate 12.

In other example forms of the electronic assembly 10 shown in FIG. 4, the back side 34 of the third substrate 32 may be directly attached to the back side 24 of the second substrate 22. In addition, although FIG. 4 only shows second and third electronic components 21, 31, additional electronic components may be directly attached to the back side 14 of the first substrate 12 or directly attached to the back side 24 of the second substrate 22 depending on the overall configuration of the electronic assembly 10.

As discussed in part above, each of the first, second and third electronic components 11, 21, 31 may be made from the same substrate material or different substrate materials (e.g., standard Si, high ohmic Si, dielectric substrates, GaAs, III/V or II/VI substrates, etc.). In addition, some, or all, of the electronic components 11, 21, 31 may be different sizes.

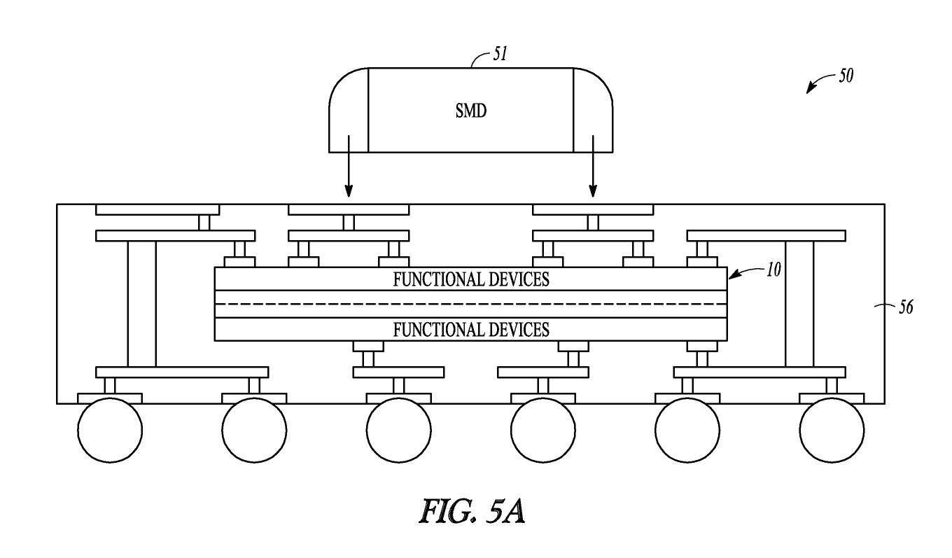

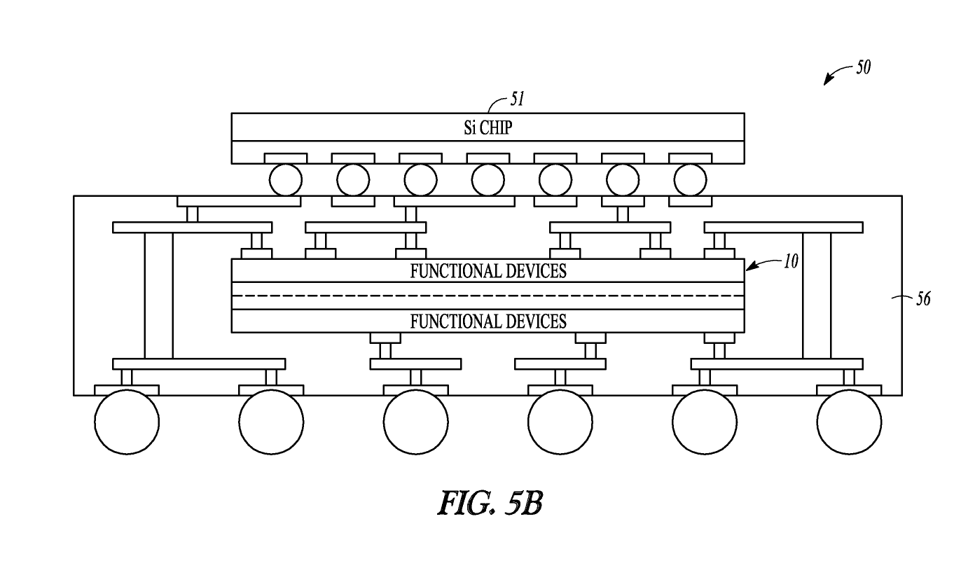

FIGS. 5A-B illustrates example electronic packages 50 that include the electronic assembly 10 shown in FIG. 3. The electronic package 50 further includes a packaging layer 56. The electronic assembly 10 is embedded within the packaging layer 56 to form the electronic package 50. It should be noted that any technique that is known now, or discovered in the future, may be used to embed the dies in laminate packages and form electrical connections between the electronic assembly 10 and the packaging layer 56.

In the example form of the electronic package 50 shown in FIGS. 5A-B, the electronic assembly 10 is embedded entirely within the packaging layer 56. Although other forms of the electronic package 50 are contemplated where only a portion of the electronic assembly 10 is embedded within the packaging layer 56.

In the example form of the electronic package 50 shown in FIG. 5A, the packaging layer 56 is a ball grid array laminate. It should be noted that the electronic assembly 10 may be embedded in other types of packaging layers (e.g., embedded wafer level ball grid arrays, PCB laminate, etc.). In addition, the packaging layer 56 may be a combination of different types of packaging layers and may potentially include a plurality of the same type of packaging layer.

By making use of the wiring levels and vias provided in the respective packages (e.g. interconnect wires and through vias in laminate packages, redistribution layer- (RDL-) wires and through mold vias (TMVs) in embedded wafer level packages, etc.) it may be possible to realize electrical connections between functional devices and circuits of the different electronic components attached back-to-back in the electronic assembly 10 as shown in FIGS. 5 & 6. In addition, by making use of the existing interconnects and vias of the respective packages it may be possible to avoid the rather expensive use and manufacture of through silicon vias (TSVs) of the prior art as shown in FIG. 2

FIGS. 5A-B illustrate example electronic packages 50 that include a third electronic component 51 attached to the packaging layer 56. It should be noted that while FIGS. 5A-B show the third electronic component 51 being attached to the top of the packaging layer 56, other forms are contemplated where the third electronic component 51 is attached to the bottom of the packaging layer 56. In addition, electronic components may be attached to the top and bottom of the packaging layer 56.

The type of third electronic component 51 that is attached to the packaging layer 56 will depend in part on the overall configuration of the electronic package 50. As examples, the third electronic component 51 in FIG. 5A may be a surface mounted device that is attached to the packaging layer 56, while in FIG. 5B the third electronic component 51 may be a die that is flip chip bonded to packaging layer 56.

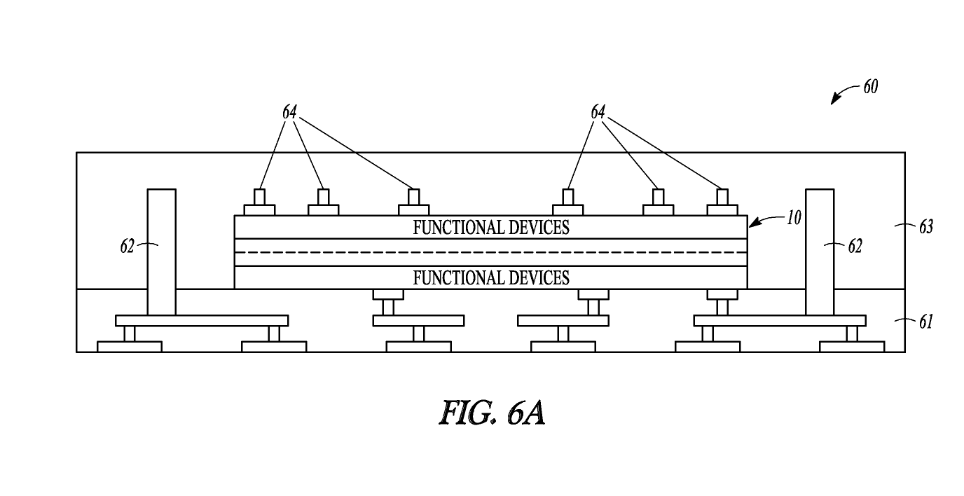

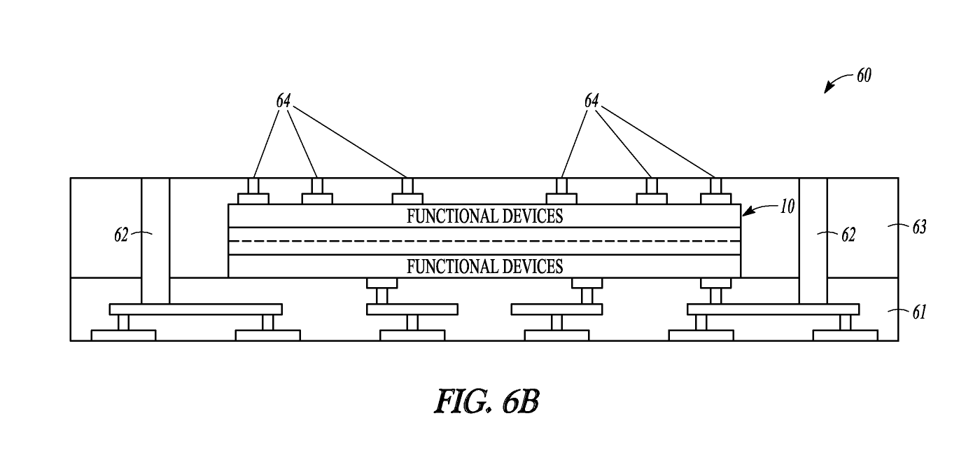

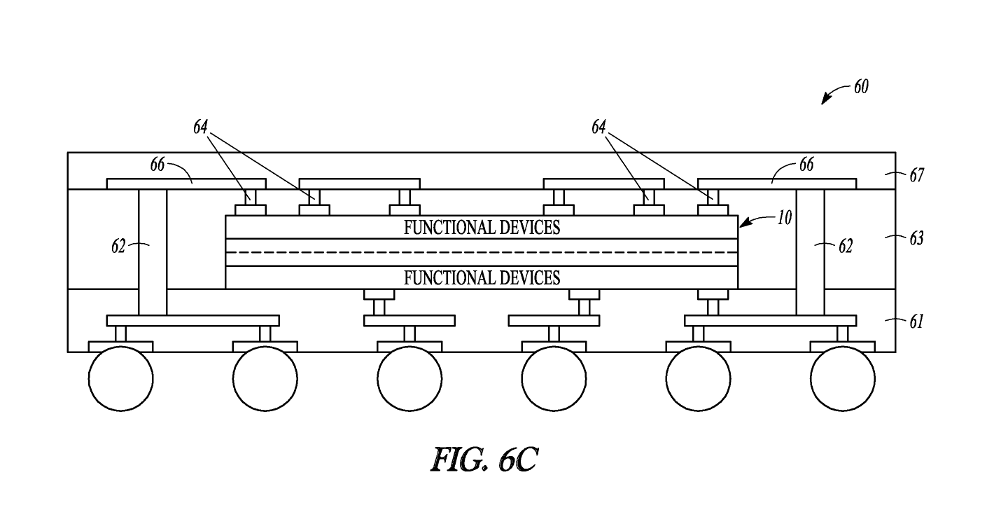

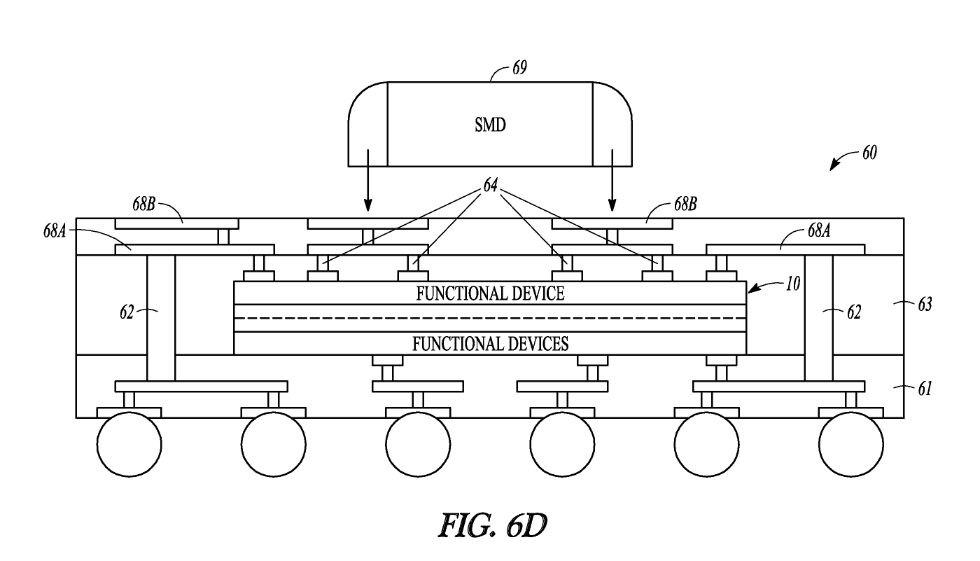

FIGS. 6A-D show other example electronic packages 60 and potential packaging process (i.e., assembly) flows for various electronic packages 50.

FIG. 6A illustrates the start of an example electronic package 60 assembly process. The process includes (i) placement of electronic assemblies 10 (with Cu pads or Cu-posts/-pillars already in place) on carrier or adhesive foil; (ii) overmolding of electronic assemblies 10 to build recon wafer/panel; (iii) removal of carrier or adhesive tape from recon wafer/panel; (iv) partial drill or etch of through mold vias (TMVs) 62 in fan-out area of recon wafer; (v) metal fill of the TMVs 62; (vi) subsequent (single or multi-level) RDL layer 61 formation providing electrical connections (i.e., RDL interconnects) to TMVs 62 and Cu pads or Cu-posts of second (‘bottom’) electronic component and providing I/O pads for solder balls or bumps.

FIG. 6B illustrates a continuation of the electronic package 60 assembly process shown in FIG. 6A. The process further includes (i) grinding the mold 63 to expose of the copper posts 64 and TMVs 62.

It should be noted that at this point in the electronic package 60 assembly process the process may continue in a variety of ways. The manner in which the example electronic package 60 assembly process continues will depend in part on the desired configuration and functionality of the electronic package 60.

FIG. 6C illustrates one example way to continue the electronic package 60 assembly process shown in FIG. 6A-B. The process may further include (i) fabricating RDL 66 on the top side of the existing electronic package 60; and (ii) forming a mold 67 on the RDL 66; and (iii) solder ball or solder bump apply on I/O pads provided in RDL layer 61 at bottom side of electronic package 60.

FIG. 6D illustrates another example way to continue the electronic package 60 assembly process shown in FIGS. 6A-B. The process may further include (i) forming multi-level top side RDLs 68A, 68B on the top side of the electronic package 60; and (ii) optionally assembling an SMD 69 (or some type of chip) onto the outermost RDL 68B.

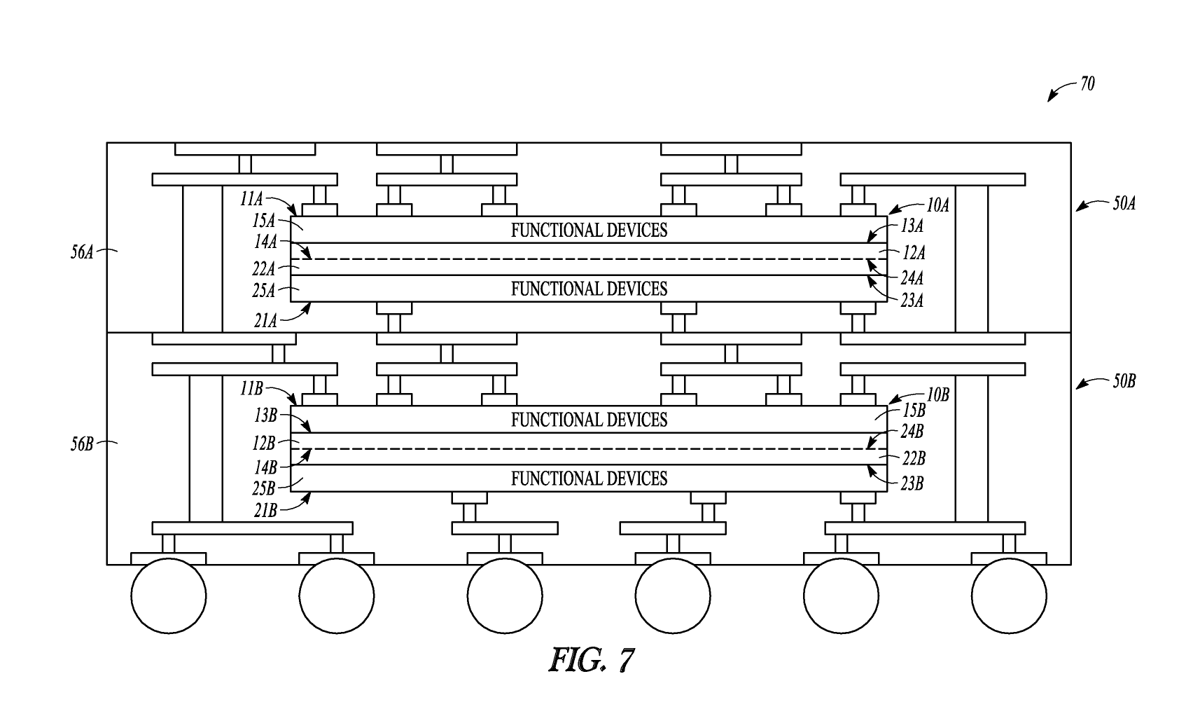

FIG. 7 illustrates an example electronic system 70 that includes two of the electronic assemblies 10A, 10B similar to the electronic assembly 10 shown in FIG. 3. It should be noted that any number of electronic assemblies may be stacked one on top of another to form the electronic system 70.

The example electronic system 70 shown in FIG. 7 includes a first electronic package 50A. The first electronic package 50A includes (i) a first electronic component 11A that includes a first substrate 12A having a front side 13A and a back side 14A and at least one electronic device 15A mounted on the front side 13A of the first substrate 12A. The first electronic package 50A further includes a second electronic component 21A that includes a second substrate 22A having a front side 23A and a back side 24A and at least one electronic device 25A mounted on the front side 23A of the second substrate 22A.

The back side 14A of the first substrate 12A is directly attached to the back side 24A of the second substrate 24B to form an electronic assembly 10A. The first electronic package 50A further includes a first packaging layer 56A. The electronic assembly 10A is embedded within the first packaging layer 56A to form the first electronic package 50A.

The example electronic system 70 further includes a second electronic package 50B that includes at least one electronic component. The second electronic package 50B is stacked onto (or positioned below in other forms) the first electronic package 50A.

In the example form illustrated in FIG. 7, the second electronic package 50B includes a third electronic component 11B that includes a third substrate 12B having a front side 13B and a back side 14B and at least one electronic device 15B mounted on the front side 13B of the third substrate 12B. The second electronic package 50B further includes a fourth electronic component 21B that includes a fourth substrate 22B having a front side 23B and a back side 24B and at least one electronic device 25B mounted on the front side 23B of the fourth substrate 22B.

The back side 24B of the fourth substrate 22B is directly attached to the back side 14B of the third substrate 12B to form the second electronic assembly 1 OB. The second electronic package 50B further includes a second packaging layer 56B. The second electronic assembly 10B is embedded within the second packing layer 56B to form the second electronic package 50B.

It should be noted that the first packaging layer 56A and the second packing layer 56B may be different types of packaging layers or the same type of packaging layers depending on the overall configuration of the electronic system 70. In addition, the first packaging layer 56A and the second packing layer 56B may be any type of packaging layer described above or discovered in the future.

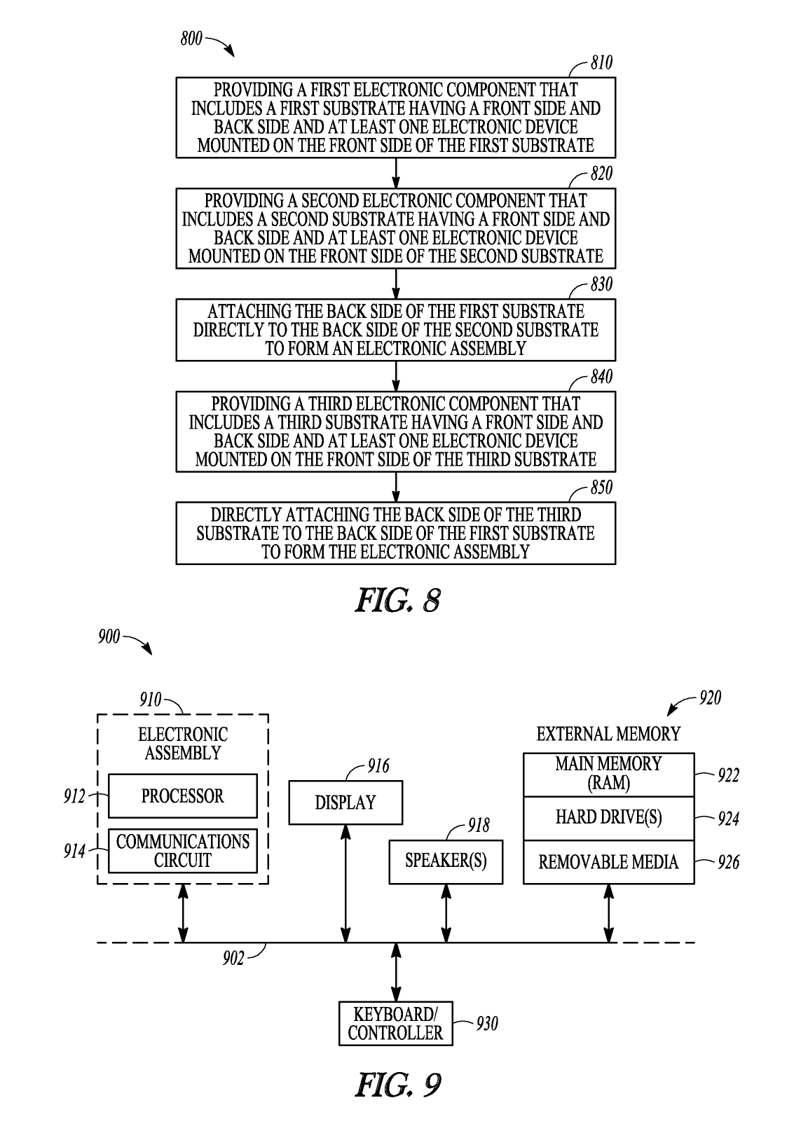

FIG. 8 is a flow diagram illustrating a method [800] of stacking electronic components 11, 21 to form an electronic assembly 10 (see, e.g., FIG. 3). The method [800] includes [810] providing a first electronic component 11 that includes a first substrate 12 having a front side 13 and back side 14 and at least electronic device 15 mounted on the front side 13 of the first substrate 12. The method [800] further includes [820] providing a second electronic component 21 that includes a second substrate 22 having a front side 23 and back side 24 and at least one electronic device 25 mounted on the front side 23 of the second substrate 22. The method [800] further includes [830] attaching the back side 14 of the first substrate 12 directly to the back side 24 of the second substrate 22 to form an electronic assembly 10.

In some forms of the method [800] the method [800] may further include [840] providing a third electronic component 31 that includes a third substrate 32 having a front side 33 and back side 34 and at least one electronic device 35 mounted on the front side 33 of the third substrate 32 (see, e.g., FIG. 4). The method [800] may further include [850] directly attaching the back side 34 of the third substrate 32 to the back side 14 of the first substrate 12 to form the electronic assembly 10. In other forms, the back side 34 of the third substrate 32 may be directly attached to the back side 24 of the second substrate 22 to form the electronic assembly 10.

FIG. 9 is a block diagram of an electronic apparatus 900 incorporating at least one electronic assembly 10, electronic package 50, 60 and/or electronic system 70 described herein. Electronic apparatus 900 is merely one example of an electronic apparatus in which forms of the electronic assemblies 10, electronic packages 50, 60 and/or electronic systems 70 described herein may be used. Examples of an electronic apparatus 900 include, but are not limited to, personal computers, tablet computers, mobile telephones, game devices, MP3 or other digital music players, etc. In this example, electronic device 900 comprises a data processing system that includes a system bus 902 to couple the various components of the electronic apparatus 900. System bus 902 provides communications links among the various components of the electronic apparatus 900 and may be implemented as a single bus, as a combination of busses, or in any other suitable manner.

An electronic assembly 910 as describe herein may be coupled to system bus 902. The electronic assembly 910 may include any circuit or combination of circuits. In one embodiment, the electronic assembly 910 includes a processor 912 which can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that may be included in electronic assembly 910 are a custom circuit, an application-specific integrated circuit (ASIC), or the like, such as, for example, one or more circuits (such as a communications circuit 914) for use in wireless devices like mobile telephones, tablet computers, laptop computers, two-way radios, and similar electronic systems. The IC can perform any other type of function.

The electronic apparatus 900 may also include an external memory 920, which in turn may include one or more memory elements suitable to the particular application, such as a main memory 922 in the form of random access memory (RAM), one or more hard drives 924, and/or one or more drives that handle removable media 926 such as compact disks (CD), flash memory cards, digital video disk (DVD), and the like.

The electronic apparatus 900 may also include a display device 916, one or more speakers 918, and a keyboard and/or controller 930, which can include a mouse, trackball, touch screen, voice-recognition device, or any other device that permits a system user to input information into and receive information from the electronic apparatus 900.

To better illustrate the method and apparatuses disclosed herein, a non-limiting list of embodiments is provided here:

Example 1 includes an electronic assembly that includes a first electronic component that includes a first substrate having a front side and a back side and at least one electronic assembly mounted on the front side of the first substrate, a second electronic component that includes a second substrate having a front side and a back side and at least one electronic assembly mounted on the front side of the second substrate, and wherein the back side of the first substrate is directly attached to the back side of the second substrate.

Example 2 includes the electronic assembly of example 1, wherein the back side of the first substrate is directly adhered to the back side of the second substrate.

Example 3 includes the electronic assembly of any one of examples 1-2, wherein the one electronic device is an active electronic device that is on the front side of the first substrate or the front side of the second substrate.

Example 4 includes the electronic assembly of any one of examples 1-3, wherein the one electronic device is a passive electronic device that is on the front side of the first substrate or the front side of the second substrate.

Example 5 includes the electronic assembly of any one of examples 1-4, wherein at least one of the first substrate and the second substrate is a silicon substrate.

Example 6 includes the electronic assembly of any one of examples 1-5, wherein at least one of the first substrate and the second substrate is a glass substrate.

Example 7 includes the electronic assembly of any one of examples 1-6, further comprising a third electronic component that includes a third substrate having a front side and a back side and at least one electronic device mounted on the front side of the third substrate, wherein the back side of the third substrate is directly attached to the back side of the first substrate.

Example 8 includes the electronic assembly of any one of examples 1-7, wherein at least one of the first substrate, second substrate and third substrate are made of a different material than the rest of the first, second and third substrates.

Example 9 includes the electronic assembly of any one of examples 1-8, wherein at least one of the first electronic component and the second electronic component is a die.

Example 10 includes an electronic package that includes a first electronic component that includes a first substrate having a front side and a back side and at least one electronic device mounted on the front side of the first substrate, a second electronic component that includes a second substrate having a front side and a back side and at least one electronic device mounted on the front side of the second substrate, wherein the back side of the first substrate is directly attached to the back side of the second substrate to from an electronic assembly, and a packaging layer, the electronic assembly being embedded within the packing layer to form the electronic package.

Example 11 includes the electronic package of example 10, wherein a portion of the electronic assembly is exposed from the packaging layer.

Example 12 includes the electronic package of any one of examples 10-11, wherein the electronic assembly is embedded entirely within the packaging layer.

Example 13 includes the electronic package of any one of examples 10-12, wherein the packaging layer is a ball grid array laminate.

Example 14 includes the electronic package of any one of examples 10-13, wherein the packaging layer is an embedded wafer level ball grid array.

Example 15 includes the electronic package of any one of examples 10-14, wherein the packaging layer includes a plurality of embedded wafer level ball grid arrays.

Example 16 includes the electronic package of any one of examples 10-15, further including a third electronic component attached to the packaging layer.

Example 17 includes the electronic package of any one of examples 10-16, wherein the third electronic component is a surface mounted electronic device attached to the packaging layer.

Example 18 includes the electronic package of examples 10-17, wherein the third electronic component is wire bonded to the packaging layer.

Example 19 includes the electronic package of any one of examples 10-18, wherein the third electronic component is attached to the packaging layer using flip chip electronic bumps.

Example 20 includes an electronic system that includes a first electronic package that includes (i) a first electronic component that includes a first substrate having a front side and back side and at least one electronic device mounted on the front side of the first substrate; (ii) a second electronic component that includes a second substrate having a front side and a back side and at least one electronic device mounted on the front side of the second substrate, wherein the back side of the first substrate is directly attached to the back side of the second substrate to from an electronic assembly; and (iii) a first packaging layer, the electronic assembly being embedded within the first packing layer to form a first electronic package, and a second electronic package that includes at least one electronic component, the second electronic assembly being stacked onto or positioned below the first electronic package.

Example 21 includes the electronic system of example 20, wherein the second electronic assembly includes a second packaging layer, the second electronic assembly being embedded within the second packing layer to form a second electronic package that is stacked onto or positioned below the first electronic package.

Example 22 includes the electronic system of any one of examples 20-21, wherein the second electronic assembly includes (i) a third electronic component that includes a third substrate having a front side and a back side and at least one electronic device mounted on the front side of the third substrate; (ii) a fourth electronic component that includes a fourth substrate having a front side and a back side and at least one electronic device mounted on the front side of the fourth substrate, wherein the back side of the fourth substrate is directly attached to the back side of the third substrate to from the second electronic assembly; and (iii) a second packaging layer, the second electronic assembly being embedded within the second packing layer to form a second electronic package that is stacked onto or positioned below the first electronic package.

Example 23 includes the electronic system of any one of examples 20-22, wherein the first packaging layer and the second packing layer are different types of packaging layers.

Example 24 includes the electronic system of examples 20-23, wherein at least one of the first packaging layer and the second packing layer is a ball grid array laminate.

Example 25 includes a method that includes providing a first electronic component that includes a first substrate having a front side and a back side and at least one electronic device mounted on the front side of the first substrate, providing a second electronic component that includes a second substrate having a front side and a back side and at least one electronic device mounted on the front side of the second substrate, and attaching the back side of the first substrate directly to the back side of the second substrate to form an electronic assembly.

Example 26 includes the method of example 25, wherein attaching the back side of the first substrate directly to the back side of the second substrate to form an electronic assembly includes directly adhering the back side of the first substrate to the back side of the second substrate.

Example 27 includes the method of any one of examples 25-26, further including providing a third electronic component that includes a third substrate having a front side and a back side and at least one electronic device mounted on the front side of the third substrate, and directly attaching the back side of the third substrate to the back side of the first substrate to form the electronic assembly.

Example 28 includes the electronic package of examples 25-27, wherein providing a first electronic component includes providing a first die.

These and other examples and features of the present electronic device, solder compositions, and related methods will be set forth in part in the detailed description.

This overview is intended to provide non-limiting examples of the present subject matter. It is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to comply with 37 C.F.R. §1.72(b), to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. An electronic assembly, comprising:
a first electronic component that includes a first substrate having a front side and a back side and at least one electronic device mounted on the front side of the first substrate;
a second electronic component that includes a second substrate having a front side and a back side and at least one electronic device mounted on the front side of the second substrate; and
wherein the back side of the first substrate is directly attached to the back side of the second substrate.

2. The electronic assembly of claim 1, wherein the back side of the first substrate is directly adhered to the back side of the second substrate.

3. The electronic assembly of claim 1, wherein the one electronic device is an active electronic device that is on the front side of the first substrate or the front side of the second substrate.

4. The electronic assembly of claim 1, wherein the one electronic device is a passive electronic device that is on the front side of the first substrate or the front side of the second substrate.

5. The electronic assembly of claim 1, further comprising a third electronic component that includes a third substrate having a front side and a back side and at least one electronic device mounted on the front side of the third substrate, wherein the back side of the third substrate is directly attached to the back side of the first substrate.

6. The electronic assembly of claim 5, wherein at least one of the first substrate, second substrate and third substrate are made of a different material than the rest of the first, second and third substrates.

7. The electronic assembly of claim 1, wherein at least one of the first electronic component and the second electronic component is a die.

8. An electronic package, comprising:
a first electronic component that includes a first substrate having a front side and a back side and at least one electronic device mounted on the front side of the first substrate;
a second electronic component that includes a second substrate having a front side and a back side and at least one electronic device mounted on the front side of the second substrate, wherein the back side of the first substrate is directly attached to the back side of the second substrate to from an electronic assembly; and
a packaging layer, the electronic assembly being embedded within the packing layer to form the electronic package.

9. The electronic package of claim 8, wherein the electronic assembly is embedded entirely within the packaging layer.

10. The electronic package of claim 8, wherein the packaging layer is an embedded wafer level ball grid array.

11. The electronic package of claim 10, wherein the packaging layer includes a plurality of embedded wafer level ball grid arrays.

12. The electronic package of claim 8, further comprising a third electronic component attached to the packaging layer.

13. An electronic system, comprising:
a first electronic package that includes (i) a first electronic component that includes a first substrate having a front side and back side and at least one electronic device mounted on the front side of the first substrate; (ii) a second electronic component that includes a second substrate having a front side and a back side and at least one electronic device mounted on the front side of the second substrate, wherein the back side of the first substrate is directly attached to the back side of the second substrate to from an electronic assembly; and (iii) a first packaging layer, the electronic assembly being embedded within the first packing layer to form a first electronic package; and
a second electronic package that includes at least one electronic component, the second electronic assembly being stacked onto or positioned below the first electronic package.

14. The electronic system of claim 13, wherein the second electronic assembly includes a second packaging layer, the second electronic assembly being embedded within the second packing layer to form a second electronic package that is stacked onto or positioned below the first electronic package.

15. The electronic system of claim 13, wherein the second electronic assembly includes (i) a third electronic component that includes a third substrate having a front side and a back side and at least one electronic device mounted on the front side of the third substrate; (ii) a fourth electronic component that includes a fourth substrate having a front side and a back side and at least one electronic device mounted on the front side of the fourth substrate, wherein the back side of the fourth substrate is directly attached to the back side of the third substrate to from the second electronic assembly; and (iii) a second packaging layer, the second electronic assembly being embedded within the second packing layer to form a second electronic package that is stacked onto or positioned below the first electronic package.

16. The electronic system of claim 15, wherein the first packaging layer and the second packing layer are different types of packaging layers.

17. The electronic system of claim 15, wherein at least one of the first packaging layer and the second packing layer is a ball grid array laminate.

18. A method, comprising:
providing a first electronic component that includes a first substrate having a front side and a back side and at least one electronic device mounted on the front side of the first substrate;
providing a second electronic component that includes a second substrate having a front side and a back side and at least one electronic device mounted on the front side of the second substrate; and
attaching the back side of the first substrate directly to the back side of the second substrate to form an electronic assembly.

19. The method of claim 18, wherein attaching the back side of the first substrate directly to the back side of the second substrate to form an electronic assembly includes directly adhering the back side of the first substrate to the back side of the second substrate.

20. The method of claim 19, further comprising:
providing a third electronic component that includes a third substrate having a front side and a back side and at least one electronic device mounted on the front side of the third substrate; and
directly attaching the back side of the third substrate to the back side of the first substrate to form the electronic assembly.
